(19) United States
(12) Patent Application Publication
(10) Pub. No.: US 2026/0332037 A1
(43) Pub. Date: Oct. 22, 2026

(54) NOISE REDUCTION IN A SWITCHING POWER CONVERTER

(71) Applicant: TEXAS INSTRUMENTS INCORPORATED, Dallas, TX (US)

(72) Inventor: Indumini Ranmuthu, Plano, TX (US)

(21) Appl. No.: 19/182,773

(22) Filed: Apr. 18, 2025

(51) Int. Cl. H02M 1/32; H02M 3/00; H02M 7/00; H05K 1/02; H05K 1/18; H05K 9/00

(52) U.S. Cl. CPC H02M 1/32; H02M 3/003; H02M 7/003; H05K 1/0218; H05K 1/181; H05K 9/0067; H05K 2201/1031

(57) ABSTRACT

A power system includes a PCB having a ground plane. A power converter on the PCB includes integrated circuits (ICs). Each IC includes a first, second, third, and fourth externally-accessible terminals coupled through respective connection structures to the ground plane of the PCB. Each IC further includes a substrate coupled to the first externally-accessible terminal. A first power stage circuit is on the substrate and has a first ground coupled to the second externally-accessible terminal. A second power stage circuit is on the substrate and has a second ground coupled to the third externally-accessible terminal. An analog circuit is on the substrate and has a third ground coupled to the fourth externally-accessible terminal. A ESD circuit is between the first ground and the substrate. A second ESD circuit is between the second ground and the substrate. A third ESD circuit is between the substrate and the third ground.

### BACKGROUND

Data centers may have a large number of very high current servers (e.g., artificial intelligence (AI) servers). Such servers may consume, for example, 2000A of current. To power the processor(s) within the servers, each server has a power supply that includes a multiphase buck converter. Given the large load current requirements, the number of phases of the multiphase buck converter may be, for example, 32. Each phase has a high side (HS) field effect transistor (FET) coupled to a low side (LS) FET capable of supplying, for example, 100A to the load. Current in the HS and LS FETs of each phase of the multiphase buck converter thus experiences a relatively high rate of change of current with respect to time (di/dt) as the HS and LS FETs turn on and off. Due to the high di/dt values, any parasitic inductance in the path of the load current may cause ringing (noise). For example, as the low side FET turns on, 100A of current begins to flow from ground of a printed circuit board on which the multiphase buck converter is mounted through metal interconnects (e.g., copper posts or bondwires) to the power ground pin of the integrated circuit containing the power stage circuits of the multiphase buck converter, and through the low side FET of the respective power stage circuit to the load. The copper posts/bondwires have parasitic inductance thereby resulting in ringing on the power ground.

### SUMMARY

In one example, a server computer includes a printed circuit board (PCB) having a ground plane. A processor is mounted on the PCB. A switching power converter is on the PCB and has an output coupled to the processor. The switching power converter includes an integrated circuit (IC) having a first externally-accessible terminal, a second externally-accessible terminal, and a third externally-accessible terminal. The first, second, and third externally-accessible terminals are coupled through respective connection structures to the ground plane of the PCB. The IC includes a substrate coupled to the first externally-accessible terminal. The IC also includes a power stage circuit on the substrate. The power stage circuit has a first ground coupled to the second externally-accessible terminal. An analog circuit is on the substrate and has a second ground coupled to the third externally-accessible terminal. A first electrostatic discharge (ESD) circuit is between the first ground and the substrate. A second ESD circuit is between the substrate and the second ground.

In another example, a power system includes a PCB having a ground plane. A power converter on the PCB includes integrated circuits (ICs). Each IC includes a first, second, third, and fourth externally-accessible terminals coupled through respective connection structures to the ground plane of the PCB. Each IC further includes a substrate coupled to the first externally-accessible terminal. A first power stage circuit is on the substrate and has a first ground coupled to the second externally-accessible terminal. A second power stage circuit is on the substrate and has a second ground coupled to the third externally-accessible terminal. An analog circuit is on the substrate and has a third ground coupled to the fourth externally-accessible terminal. A ESD circuit is between the first ground and the substrate. A second ESD circuit is between the second ground and the substrate. A third ESD circuit is between the substrate and the third ground.

In yet another example, an IC includes a substrate coupled to a first externally-accessible terminal, and includes a power stage circuit on the substrate. The power stage circuit has a first ground coupled to a second externally-accessible terminal. An analog circuit is on the substrate. The analog circuit has a second ground coupled to a third externally-accessible terminal. A first electrostatic discharge (ESD) circuit is between the first ground and the substrate. A second ESD circuit is between the substrate and the second ground.

### BRIEF DESCRIPTION OF THE DRAWINGS

FIG. 1 is a system diagram of a server computer, in an example.

FIG. 2 is a circuit schematic of an example power stage circuit within a switching power converter.

FIG. 3 is a schematic diagram of an integrated circuit illustrating a substrate package ground, an analog ground, and a power ground, in an example.

FIG. 4 is a schematic diagram of another integrated circuit illustrating a substrate package ground, an analog ground, and a power ground, in another example.

### DETAILED DESCRIPTION

The same reference numbers or other reference designators are used in the drawings to designate the same or similar (either by function and/or structure) features.

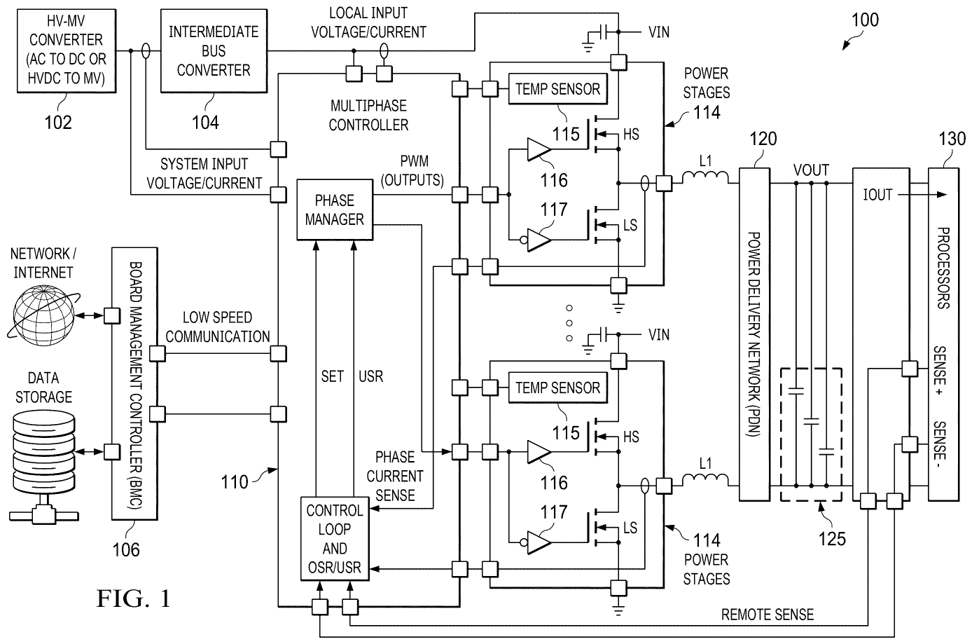

FIG. 1 is a system diagram of an example server computer 100, in an example. The principles described herein are applicable to other types of systems as well. Server computer 100 includes voltage converters 102 and 104, a board management controller (BMC) 106, a multiphase controller 110, power stage circuits 114, a power delivery network 120, and one or more processors 130. Processor 130 may include central processing units (CPUs), graphics processor units (GPUs), etc. Voltage converter 102 may convert a higher voltage to a medium voltage. In one example voltage converter 102 converts an alternating current (AC) voltage to a direct current (DC) voltage. In another example, voltage converter 102 converts a higher DC voltage to a medium DC voltage. Voltage converter 104 further converts the medium voltage from voltage converter 102 to an input voltage for multiphase controller 110, power stage circuits 114, and other components.

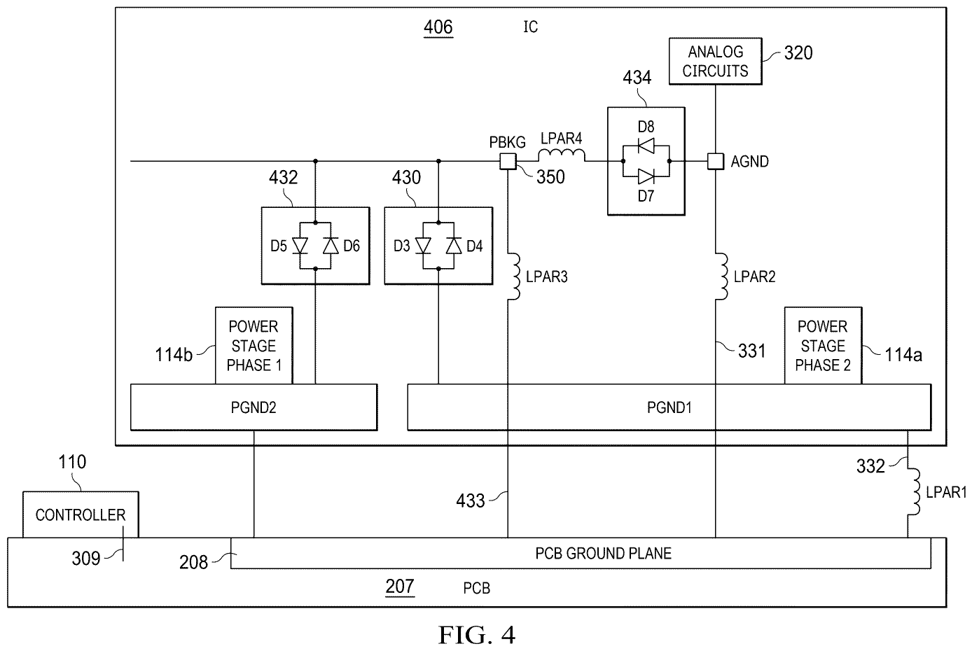

Multiphase controller 110 and power stage circuits 114 form a multiphase power converter such as a multiphase buck converter. The multiphase power converter has an output coupled to, for example, processor 130 and other components within the server computer 100. Each power stage circuit 114 includes a high side (HS) transistor coupled to a low side (LS) transistor. The connection between the HS and LS transistors is a switching terminal which is also coupled to an inductor L1. Driver 116 within each power stage circuit 114 turns the HS transistor on and off based on a pulse width modulation (PWM) control signal from multiphase controller 110. Similarly, driver 117 within each power stage circuit 114 turns the LS transistor on and off based on the PWM signal from multiphase controller 110. Each power stage circuit 114 may include a temperature sensor 115 and may include one or more analog circuits. Such analog circuits (shown in FIGS. 4 and 5 and described below) may, for example, sense current through the HS and/or LS transistors, provide temperature sensing using the temperature sensor 115, and convert the PWM signal from multiphase controller 110 to control signals that turn on and off the HS and LS transistors. The multiphase buck converter includes one power stage circuit 114 for each of the phase. For example, a 32 phase buck converter includes 32 power stage circuits 114. Power delivery network 120 couples together the inductors L1 from the power stage circuits 114. Output capacitors 125 are charged to the voltage that is used to power processor 130. In some examples, server computer 100 may flow 1000 amperes or 2000 amperes of current through it. Each stage of the multiphase buck converter may be capable of flowing 100 amperes of current.

In one example, server computer 100 includes a printed circuit board (PCB) (not shown in FIG. 1) on which one or more of the components in FIG. 1 are mounted. The multiphase controller 110 may be fabricated as one integrated circuit (IC), which is mounted on the PCB. One or more of power stage circuits 114 may be fabricated on a separate IC, also mounted on the PCB. Processor 130 may be mounted on the PCB as well. Any suitable number of power stage circuits 114 can be part of one IC. For example, two or four power stage circuits 114 can be on a single IC. In an example, in which four power stage circuits 114 are on a single IC and the multiphase buck converter includes 32 phases, eight ICs containing power stage circuits 114 are mounted on the PCB.

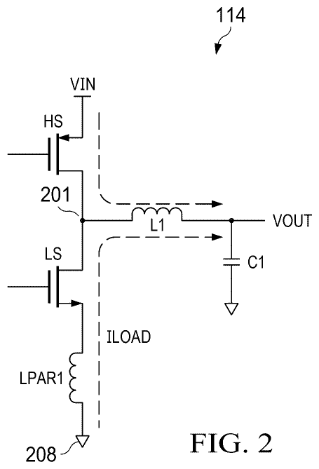

FIG. 2 is a circuit diagram of at least a portion of a power stage circuit 114. In this example, the HS transistor is a p-channel field effect transistor (PFET) and the LS transistor is an n-channel field effect transistor (NFET). In some examples, the HS transistor is an NFET. The drains of the HS and LS transistors are coupled together the switching terminal 201. One terminal of inductor L1 is coupled to the switching terminal 201, and the other terminal of inductor L1 is coupled to the output of the multiphase buck converter. A capacitor C1 (e.g., capacitors 125 in FIG. 1) is coupled to the output. The source of the HS transistor is coupled to the input voltage VIN. The PCB on which the power stage circuit 114 is mounted includes a PCB ground plane 208. The source of the LS transistor is coupled to the PCB ground plane 208. A parasitic inductance Lpar1 is present in the metallization that connects the PCB ground plane 208 to the power ground of the IC containing power stage circuit 114. For example, if the IC containing power stage circuit 114 is coupled to the PCB through bondwires or metal (e.g., copper) posts, parasitic inductance Lpar1 includes the parasitic inductance of the bondwires or metal posts.

Upon turning on the LS transistor, current ILOAD begins to flow from the PCB ground plane 208, through the LS transistor, and through inductor L1 to the load (e.g., processor 130) and to capacitor C1 (to recharge the capacitor). The combination of the rapid turn on of the LS transistor and the large magnitude of current ILOAD (e.g., 100 A), the rate of change of current ILOAD (dILOAD/dt) can be large, which can cause significant ringing on the power ground of the power stage circuit 114, described below.

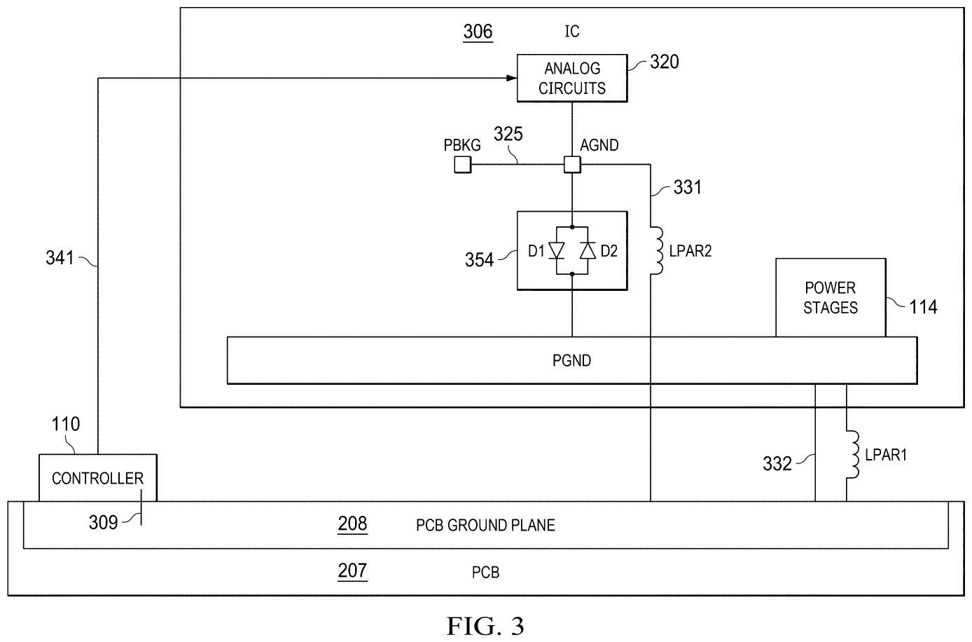

FIG. 3 is a diagram of an integrated circuit (IC) 306 containing one or more power stage circuit 114 and analog circuits 320. Analog circuits 320 may perform one or more functions such as current sensing, temperature sensing, converting a PWM signal to control signals for the HS and LS transistors, etc. IC 306 also includes an analog ground AGND, a power ground PGND, and a package substrate ground PBKG. The IC includes a package substrate on which the circuitry of power stage circuit 114 and analog circuits 320 are fabricated. The package substrate is connected to ground. In the example of FIG. 3, PBKG is connected to AGND through metallization 325 (e.g., a trace) within the IC. Accordingly, PBKG is not an externally-accessible terminal (e.g., a pin) of IC 306. In this example AGND and PGND are externally-accessible terminals (e.g., pins) of IC 306. AGND is coupled to the analog circuits 320 and provides the ground reference for the analog circuits 320. PGND provides the ground reference for power stage circuits 114. For example, the source of the LS transistor within each power stage circuit 114 may be coupled to PGND. IC 306 also includes an electrostatic discharge (ESD) circuit 354 coupled between PGND and AGND to protect circuitry within IC 306 such as analog circuits 320. In one example, the ESD circuit 354 includes diodes D1 and D2. The anode of diode D2 is coupled to the cathode of diode D1 and to PGND. Similarly, the anode of diode D1 is coupled to the cathode of diode D2 and to AGND. In the event of a large voltage on PGND, diode D2 turns on thereby providing a low impedance current path to AGND. Similarly, in the event of a large voltage on AGND, diode D1 turns on providing a low impedance current path to PGND.

FIG. 3 also illustrates a PCB 207 on which components of the multiphase power converter such as controller 110 and IC 306 are mounted. PCB 207 includes multiple layers including a PCB ground plane 208. In the example of FIG. 3, AGND and PGND are coupled to PCB ground plane 208 via, for example, connection structures (e.g., metal posts, bondwires) 331 and 332, respectively, as noted above. The parasitic inductance Lpar1 of the connection structure 332 is shown in FIG. 3. Parasitic inductance Lpar2 represents the parasitic inductance of metal connection 331 interconnecting AGND to the PCB ground plane 208. Controller 110 also is shown as an IC mounted on the PCB 207. The controller's ground is coupled to PCB ground plane 208 via metal connections 339. Controller 110 provides one or more control signals 341 to analog circuits 320.

AGND may receive noise from either or both of PGND and PBKG. The noise may be ringing on PGND or PBKG due to relatively large di/dt values described above. For example, noise on PGND may cause diode D2 within ESD circuit 354 to turn on thereby allowing some of the PGND's noise from infecting AGND. Because PBKG is connected to AND through metallization 325, any noise on PBKG may directly pass to AGND. Because AGND represents the ground reference for analog circuits 320, noise on AGND may disrupt the operation of analog circuits 320. For example, controller 110 generates control signals 341 for analog circuits. The voltage level of control signals 341 generated by controller 110 is with reference to the ground of controller 110. Noise on AGND may not be present on the controller's ground. Accordingly, a voltage difference may exist between AGND and the controller's ground. Analog circuits 320 may interpret, example, a logic high control signal 341 from controller 110 as a logic low because AGND is at higher voltage than the controller's ground.

FIG. 4 is a diagram of an IC 406 mounted on PCB 207 and containing one or more power stage circuits 114, such as power stage circuits 114a and 114b, and analog circuits 320. The configuration of PBKG and ESD circuits for IC 406 is different than for IC 306. For IC 406, PBKG is an externally-accessible terminal (e.g., a pin) of IC 406 as also is the case for AGND and PGND. Instead of PBKG being directly connected to AND internally within the IC (e.g., via a trace), PBKG in FIG. 4 is coupled to PCB ground plane 208 via a metal connection structure 433 (e.g., metal post, bondwire). Parasitic inductance Lpar3 represents the parasitic inductance of connection structure 433.

The example of FIG. 4, power stage circuit 114a is coupled to its respective power ground PGND1, and power stage circuit 114b is coupled to its respective power ground PGND2. PGND1 and PGND2 are externally-accessible terminals of IC 406. IC 406 includes an ESD circuit 430 between PGND1 and PBKG, and another ESD circuit 432 between PGND2 and PBKG. IC 406 also includes an ESD circuit 434 between PBKG and AGND. In this example, IC 406 does not include an ESD circuit (e.g., ESD circuit 354, FIG. 3) between AGND and PGND1 or between AGND and PGND2. ESD circuit 430 includes diodes D3 and D4. ESD circuit 432 includes diodes D5 and D6. ESD circuit 434 includes diodes D7 and D8. The diodes within each of ESD circuits 430, 432, and 434 are coupled together as described above regarding ESD circuit 354.

The technical advantage of the grounding and ESD circuit configuration of IC 406 relative to IC 306 is that noise on PGND (either PGND1 or PGND2) is less likely to be present on AGND. The current path from PGND1 to AGND in FIG. 4 includes two ESD circuits 430 and 434, and not, as in FIG. 3, only one ESD circuit 354. Accordingly, for a voltage on PGND1 that is large enough to pass through ESD circuits 430 and 434, the forward voltage drop of diode D4 and the forward voltage drop of diode D7 would reduce the resulting voltage once it is present on AGND. Further, the impedance of parasitic inductance Lpar3 between PBKG and the PCB ground plane 208 is smaller than the impedance of diode D7. Accordingly, noise on PGND1 may pass through diode D4 but then pass directly through the lower impedance path to PCB ground plane 208 rather than the higher impedance path through diode D7.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

While the use of particular transistors is described herein, other transistors (or equivalent devices) may be used instead with little or no change to the remaining circuitry. For example, a field effect transistor (“FET”) (such as an n-channel FET (NFET) or a p-channel FET (PFET)), a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors or other types of device structure transistors. Furthermore, the devices may be implemented in/over a silicon substrate (Si), a silicon carbide substrate (SiC), a gallium nitride substrate (GaN) or a gallium arsenide substrate (GaAs).

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description.

Modifications are possible in the described examples, and other examples are possible, within the scope of the claims.

What is claimed is:

1. A server computer, comprising:
a printed circuit board (PCB) having a ground plane;
a processor; and
a switching power converter on the PCB and having an output coupled to the processor, the switching power converter including an integrated circuit (IC) having a first externally-accessible terminal, a second externally-accessible terminal, and a third externally-accessible terminal, the first, second, and third externally-accessible terminals coupled through respective connection structures to the ground plane of the PCB, the IC including:
a substrate coupled to the first externally-accessible terminal;
a first circuit on the substrate, the first circuit having a first ground coupled to the second externally-accessible terminal;
a second circuit on the substrate, the second circuit having a second ground coupled to the third externally-accessible terminal;
a first electrostatic discharge (ESD) circuit between the first ground and the substrate; and
a second ESD circuit between the substrate and the second ground.

2. The server computer of claim 1, wherein the connection structures include metal posts.

3. The server computer of claim 1, wherein the first ESD circuit includes a first diode coupled to a second diode, and the second ESD circuit includes a third diode coupled to a fourth diode.

4. The server computer of claim 1, wherein the first circuit is a first power stage circuit, the IC includes a fourth externally-accessible terminal coupled to the ground plane of the PCB, and the IC further includes:
a second power stage circuit on the substrate, the second power stage circuit having a third ground coupled to the fourth externally-accessible terminal; and
a third ESD circuit between the third ground and the substrate.

5. The server computer of claim 1, wherein the server computer is configured to flow at least 1000 amperes.

6. The server computer of claim 1, wherein the first circuit includes a power stage circuit.

7. A power system, comprising:
a printed circuit board (PCB) having a ground plane;
a power converter on the PCB, the power converter including a plurality of integrated circuits (ICs), each IC including a first externally-accessible terminal, a second externally-accessible terminal, a third externally-accessible terminal, and a fourth externally-accessible terminal, the first, second, third, and fourth externally-accessible terminals coupled through respective connection structures to the ground plane of the PCB, each IC further including:
a substrate coupled to the first externally-accessible terminal;
a first power stage circuit on the substrate having a first ground coupled to the second externally-accessible terminal;
a second power stage circuit on the substrate having a second ground coupled to the third externally-accessible terminal;
an analog circuit on the substrate, the analog circuit having a third ground coupled to the fourth externally-accessible terminal;
a first electrostatic discharge (ESD) circuit between the first ground and the substrate;
a second ESD circuit between the second ground and the substrate; and
a third ESD circuit between the substrate and the third ground.

8. The power system of claim 7, wherein each connection structure includes metal posts.

9. The power system of claim 7, wherein each of the first, second, and third ESD circuits includes a first diode coupled to a second diode.

10. An integrated circuit (IC), comprising:
a substrate coupled to a first externally-accessible terminal;
a power stage circuit on the substrate, the power stage circuit having a first ground coupled to a second externally-accessible terminal;
a first circuit on the substrate, the first circuit having a second ground coupled to a third externally-accessible terminal;
a first electrostatic discharge (ESD) circuit between the first ground and the substrate; and
a second ESD circuit between the substrate and the second ground.

11. The IC of claim 10, wherein the power stage circuit is a first power stage circuit, and the IC includes:
a second power stage circuit having a third ground coupled to a fourth externally-accessible terminal; and
a third ESD circuit between the third ground and the substrate.

12. The IC of claim 10, wherein each of the first and second ESD circuits includes a first diode coupled to a second diode.

13. An integrated circuit (IC), comprising:
a substrate coupled to a first externally-accessible terminal;
a power stage circuit on the substrate, the power stage circuit having a first ground coupled to a second externally-accessible terminal;
an analog circuit on the substrate, the analog circuit having a second ground coupled to a third externally-accessible terminal;
a first electrostatic discharge (ESD) circuit between the first ground and the substrate; and
a second ESD circuit between the substrate and the second ground.

14. The IC of claim 13, wherein each of the first ESD circuit and the second ESD circuit includes a first diode coupled to a second diode, and the second ESD circuit includes a third diode coupled to a fourth diode.

15. The IC of claim 13, wherein the power stage circuit is a first power stage, the IC includes:
a second power stage circuit on the substrate, the second power stage circuit having a third ground coupled to a fourth externally-accessible terminal; and
a third ESD circuit between the third ground and the substrate.
